(19) United States
(12) Patent Application Publication
(10) Pub. No.: US 2012/0000530 A1
(43) Pub. Date: Jan. 5, 2012

(54) DEVICE FOR HARNESSING SOLAR ENERGY WITH INTEGRATED HEAT TRANSFER CORE, REGENERATOR, AND CONDENSER

(76) Inventor: Mark W. Miles, San Francisco, CA (US)

(21) Appl. No.: 12/830,273

(22) Filed: Jul. 2, 2010

(51) Int. Cl. H01L 31/0232; F28D 17/00; F28D 15/00

(52) U.S. Cl. 136/259; 165/104.19; 165/10

(57) ABSTRACT

An integrated heat transfer core device for harnessing solar energy is disclosed. The device has a heat transfer core, a regenerator; and a condenser. All of the aforesaid components are integrated. The heat transfer core has a thermal conduction mitigation component to mitigate heat losses from a working fluid due to conduction. Further, the heat transfer core may be packaged in a heat transfer core package that includes a light focusing component to concentrate solar radiation onto each heat transfer core. Solar power systems utilizing the integrated heat transfer core device are also disclosed.

### FIELD

Embodiments of the invention relate to devices and methods to harness solar radiation as an energy source.

### BACKGROUND

Solar collectors are devices designed to convert solar radiation into heat that can be used to perform work.

One new design of a solar collector was described in co-pending U.S. patent application Ser. No. 12/623,337, the specification of which is hereby incorporated by reference. The design of the collector is illustrated in FIG. 1. The improved performance of this collector derives from the fact that a light absorbing heat transfer core (HTC) resides within an infrared absorbing working fluid such as water. The HTC includes a light absorption component that converts incident solar flux into heat, which is transferred to the working fluid as it passes through the body of the HTC. Heat that radiates from the HTC in the form of infrared radiation is absorbed by the working fluid and thus prevented from escaping to the ambient environment. The lower radiative losses result in overall improved performance of the collector.

### SUMMARY

According to one aspect of the invention, there is provided a heat transfer core, comprising:

At least one light absorption element and at least one fluid transfer element, and at least one thermal conduction mitigation element

According to a second aspect of the invention a light concentrating optical array is integrated into the heat transfer core.

According to a third aspect of the invention a regenerating component and a condensing component are integrated into the heat transfer core.

Other aspects will be apparent from the description, claims, and drawings.

### BRIEF DESCRIPTION OF THE DRAWINGS

FIG. 1a of the drawings shows a side view of a non-integrated heat transfer core for a solar collector.

FIG. 1b of the drawings shows a cross-section through the heat transfer core of FIG. 1a.

FIG. 2 of the drawings illustrates heat flow paths in single and multi-layer wicks, and the construction of a multi-layer wick, in accordance with one embodiment.

FIG. 3 of the drawings is a schematic diagram of a multi-layer wick with a spiral-insulating wick, in accordance with one embodiment.

FIG. 4 of the drawings shows two diagrams illustrating a single element heat transfer core package, and a multiple element heat transfer core package.

FIG. 5 of the drawings shows three diagrams illustrating a Fresnel concentrating array, a portion of a heat transfer core integrated with a single sided Fresnel concentrating array, and packaged heat transfer core integrated with a double sided Fresnel concentrating array

FIG. 6 of the drawings shows a schematic of a solar thermally driven rankine cycle.

FIG. 7 of the drawings illustrate cross section and side views of a heat transfer core package integrated with a Fresnel concentrator .array, a regenerator, and a condenser.

FIG. 8 shows examples of solar power systems, in accordance with embodiments of the invention.

### DETAILED DESCRIPTION

In the following description, for purposes of explanation, numerous specific details are set forth in order to provide a thorough understanding of the invention. It will be apparent, however, to one skilled in the art that the invention can be practiced without these specific details.

Reference in this specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other.

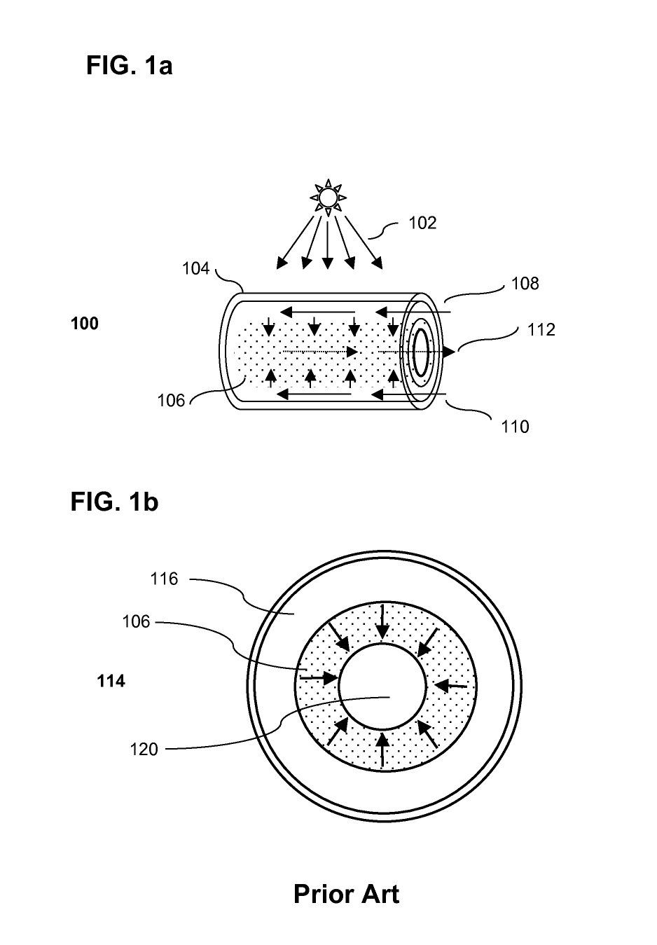

FIG. 1a shows a non-integrated heat transfer core 100 which was described in U.S. patent application Ser. No. 2/623,337. The core 100 is illuminated by solar flux 102. Transparent housing 104 allows for the passage of solar flux 102, so that it may be absorbed by light absorbing wick 106. In one embodiment, light absorbing wick 106 may comprise a copper metal foam matrix whose outer surface has been coated with a thin film or stack of thin films such that light that is incident on the outer surface is completely or substantially absorbed. The light that is absorbed is subsequently converted into heat, thus the temperature of the wick rises. The internal structure of the foam is porous thus capillary forces can act on a working fluid to pump it through the wick. Working fluid 108, which may be water, for example, flows into the space between the transparent housing 104, and the light-absorbing wick 106. Via the aforementioned capillary pumping, this fluid is pulled into the body of the wick where it is heated via conduction and eventually leaves the collector in the form of a vapor 112. This design is advantageous because the heat, which escapes from the wick 106 in the form of infrared radiation, is absorbed by the working fluid if that fluid is water or some other fluid with suitable infrared absorption properties. The heat, which is absorbed by the working fluid, is recycled back to the wick 106 by virtue of the fact that the working fluid is flowing into the wick 106.

Referring now to Figure lb of the drawings reference numeral 114 indicates a cross sectional view of the core 100. Annulus 116 is the region where the working fluid enters the core 100, light absorbing wick 106 pumps the water in the direction indicated by the arrows, and inner conduit 120 provides a means whereby the resulting vapor may escape.

It should be noted that while the cross sectional view illustrated in the prior art indicates a circular shaped core; other shapes may be advantageous from the stand point of efficiently capturing light. These include, but are not limited to, ovals, ellipses, and other shapes which can maximize the effective light capturing capacity of the core while not compromising mechanical integrity.

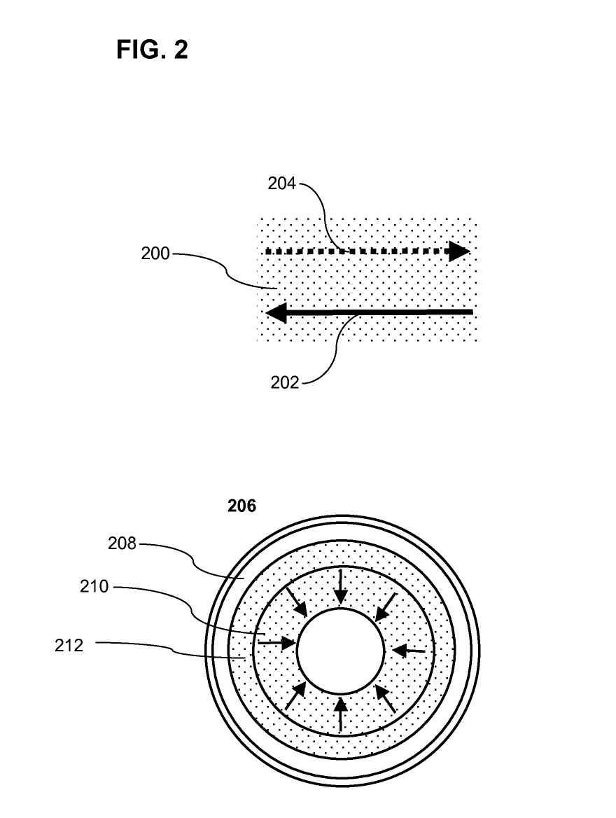

FIG. 2 of the drawings shows a wick segment 200 with working fluid 202 propagating through it in one direction and carrying heat via advection, a phenomenon whereby the heat is transported via currents in the working fluid. Heat 204, is shown propagating in the opposite direction via conduction in the working fluid. In order for the solar collector to achieve improved performance, the rate of heat transfer via advection must be greater than the rate of heat transfer via conduction. Given a fixed value for the thermal conductivity of the working fluid, this ratio can primarily be controlled by varying the flow rate or velocity of the working fluid. The higher the flow rate, the higher the rate of heat transfer via advection.

206 indicates a cross-section through a heat transfer core, in accordance with one embodiment, with a two-layer wick structure which provides as means of controlling the velocity of the working fluid and therefore the rate of advection vs. conduction. Fluid annulus 208 allows the passage of the working fluid so that it may be absorbed by outer wick 212, and subsequently absorbed by inner wick 210. Inner wick 210 is of a design similar to that described in the prior art, and performs the function of transferring heat generated through light absorption, to the working fluid via conduction. Outer wick 212 is similar in structure. That is to say that is a porous medium of some fixed or possibly variable porosity, and may be of a closed or open celled nature. The material used in its fabrication however, is required to be substantially transparent to visible light, and to have a thermal conductivity which is much lower than that of the inner wick. Preferably, the thermal conductivity of the outer wick is lower than that of the working fluid. By varying the porosity of the outer wick, or the ratio of material to open space, it is possible to vary the local velocity of the fluid as it propagates through the outer wick. For example, if the working fluid before entering the wick has an average velocity of V, and the porosity of the wick is 50%, then the average velocity of the fluid within the wick will have a value of 2*V, or twice the original velocity. This provides a mechanism for lowering the amount of heat transported in the working fluid via conduction by increasing the velocity of the working fluid within the outer wick. The use of a transparent material in the outer wick allows the incident solar flux to be absorbed in the inner wick. Incorporating materials with low thermal conductivity such as glass, or plastic, contributes to lowering the amount of heat that is transported via conduction within the material of the wick itself. Materials for the outer wick include but are not limited to, glass, silicon dioxide, and Teflon. The wick may be fabricated using a number of techniques utilized by those skilled in the art including sintering, and glass foaming techniques.

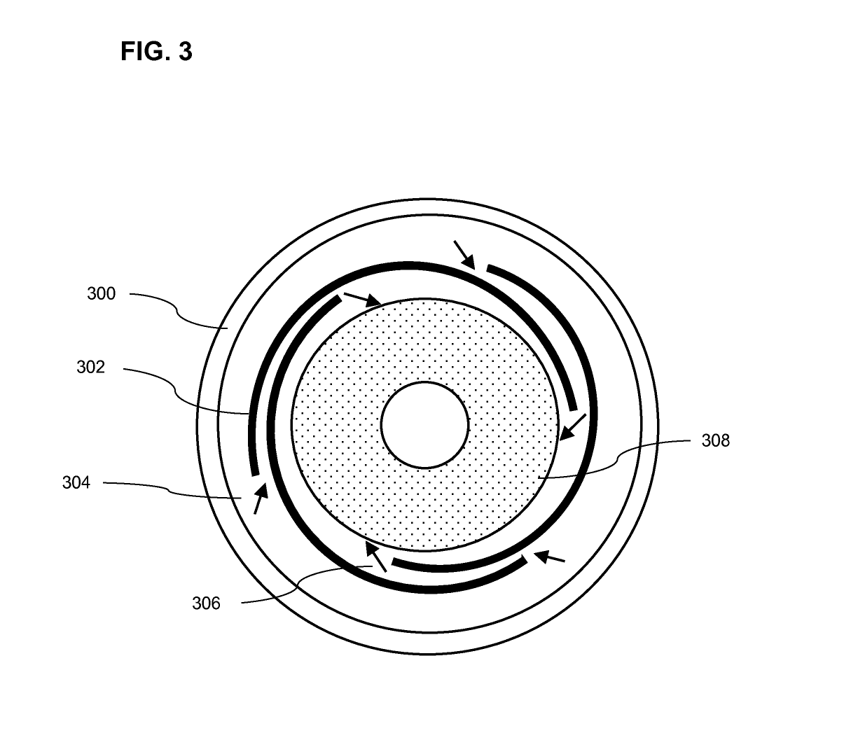

FIG. 3 illustrates a cross- section through a heat transfer core, in accordance with another embodiment, with an outer wick of alternate construction. Referring to FIG. 3, transparent housing 300 provides a mechanism for working fluid 304, to be transported into spiral outer wick 302 in the direction indicated by the arrows. The working fluid is transported to inner wick 308. Spiral outer wick 302, is constructed from two or more transparent thin film layers which have low thermal conductivity, are non-porous, and generally resistant to high temperatures. The layers are wrapped in a spiral fashion, with a constant or perhaps variable spacing maintained between the layers during the wrapping process. One mechanism for defining this space is to incorporate glass or silica spacer balls that are commercially available in sizes ranging from submicron to millimeters. The size of the spacing vs. the thickness of the layers defines the effective porosity of this structure. The spiral configuration is advantageous because it allows the propagation distance of the working fluid, to be. increased without increasing the radius of the outer wick. Increasing the propagation distance'in a wick made from sintered or an open celled matrix will cause the radius of the wick to grow correspondingly. Lengthening the propagation distance is useful because it provides yet another mechanism for lowering the rate of heat transport via conduction. Materials suitable for building a spiral wick include but are not limited to, thin glass, Teflon, and other plastics. Other configurations and fluid flow paths are possible as long as the goals of lengthening the fluid flow path and/or increasing fluid flow velocity while allowing for the transmission of light to the inner wick are maintained.

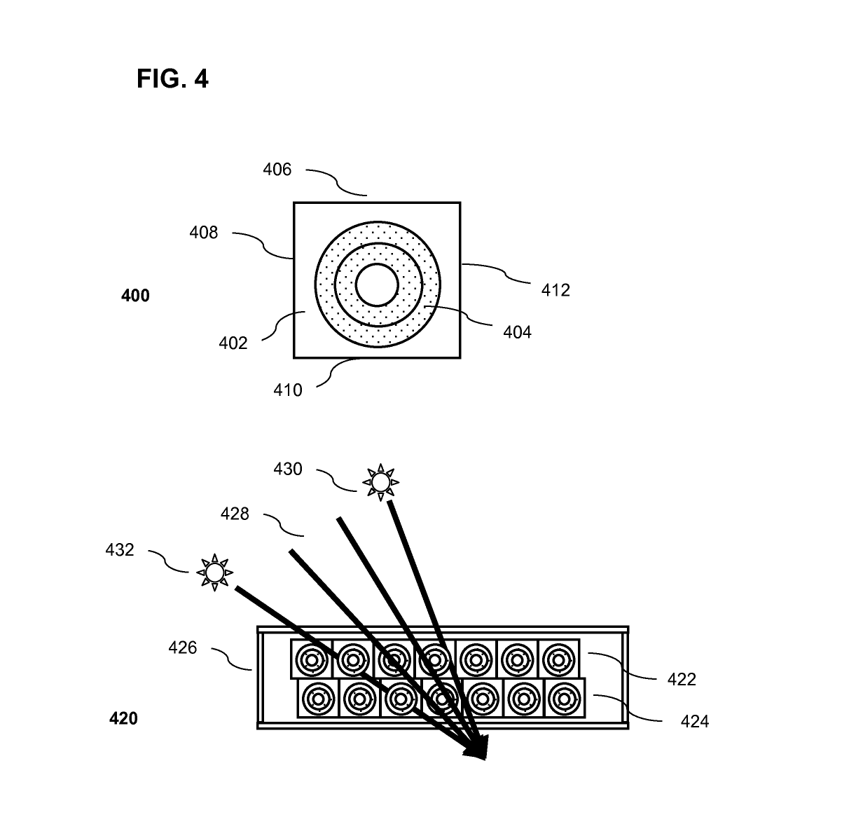

FIG. 4 of the drawings shows a cross-section through a heat transfer core package 400, in accordance with another embodiment. Referring to FIG. 4, heat transfer core (HTC) package 400 comprises a hollow rectangular glass rod 402, with a heat transfer core 404, located within. Side 406 may be coated with an anti-reflective coating, e.g. a commercially available anti-reflective coating. Sides 408, 410, and 412 may be coated with a thin material film or an adhesive whose function is to facilitate bonding with adjacent HTC elements.

Reference numeral 420 indicates a HTC package comprising two layers of HTC elements, 422 and 424, which have been bonded together. This bonding may be accomplished using an environmentally robust adhesive, i.e. one capable of withstanding exposure to extremes of heat and UV radiation. This bond may also be accomplished via a low temperature anodic bonding if the bond material is a film like silicon or aluminum. This process and other relevant processes are well understood in industry and by those skilled in the art of bonding glass. The bonding technique must not substantially inhibit the propagation of light between adjacent HTC elements. HTC package 420 is shown packaged in a vacuum housing 426 that both supports an internal high vacuum, and allows for solar flux 428, to be incident on HTC layers 422 and 424.

In the embodiment illustrated in FIG. 4, the HTC package comprises two layers in order to increase the fill factor (i.e. light absorption area), and to accommodate changes in the position of the sun. The thickness of the walls of the glass rods is determined by the amount of internal pressure they must support, among other factors. This creates a separation between adjacent HTC elements and thus reduces the overall fill factor of the resulting HTC package because of the light that is lost between the elements. By using two layers this lost light can be captured.

In most cases the HTC package will be oriented in an east-west configuration, that is, the HTC elements are oriented lengthwise parallel to the course that the sun takes during a day. However, over the course of a year the inclination of the sun varies by about 47 degrees. In one embodiment, by staggering the position of the two HTC layers 422 and 424, it is possible to optimize the HTC package so that for a given range of sun inclination angles, all of the light that is incident on the HTC package will be absorbed by the HTC elements contained within. In one embodiment, the aforesaid staggering of the elements may be set during manufacture to be optimized for the geographic latitude of the location where the HTC package will be deployed.

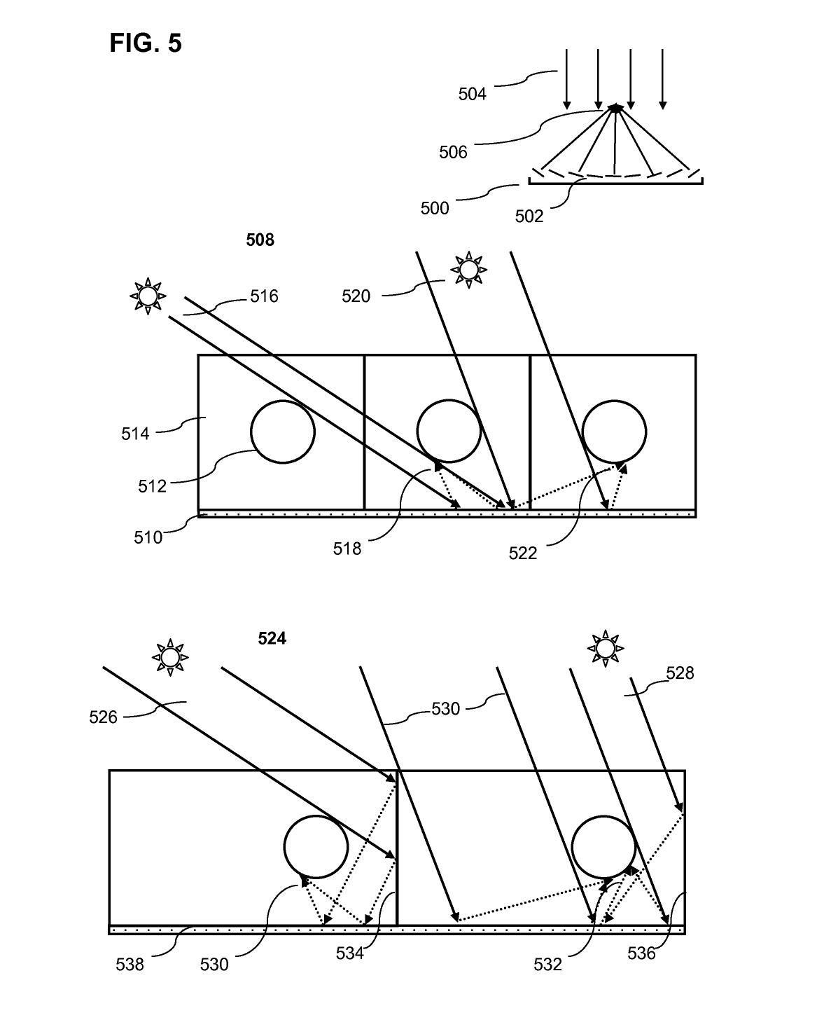

Referring to FIG. 5, an alternative HTC package design is illustrated. Fresnel plate 500 is shown with an array of linear mirrors 502, embossed or etched into its surface. The Fresnel plate may comprise one or more of a number of materials such as glass, metal, or plastic depending on the requirements for thermal expansion and material compatibility. The reflecting surface must have a precise geometry and be highly reflective. Fresnel plate 500 is shown with a mirror array 502, whose orientation is such that incident light 504 is reflected to focal point 506. Fresnel plates are useful because they allow for complex reflective patterns to be defined in a two-dimensional space. HTC package 508 is shown with three HTC elements bonded together. Absorbing wick 512 defines the physical extent of the absorbing region within each HTC element. Fresnel plate 510 is physically bonded to the bottom side, a single side, of the HTC package in a way that allows for the transmission of light into the HTC package with minimal degradation. The Fresnel plate and overall geometry of the HTC package 508 are defined to concentrate light onto the surface of each absorbing wick 512. Regardless of the time of the year, some fraction of the light that is incident on the HTC package will strike some portion of absorbing wicks 512 directly. Fresnel plate 510 can be designed to redirect light that would pass between the HTC elements back to a linear focal point on the side of the absorbing wick that is not exposed directly to the solar flux. Light path 516, which occurs at a time of the year with the lowest sun inclination, is redirected to focal point 518 on the left edge of the middle absorbing wick 518. During the course of the year the angle of the incident light gradually changes in a way such that the position of the focal point on each wick moves across the width of the wick. Light at the time of the year with the sun's inclination at its highest follows light path 520 and is focused on the other extreme of each wick at focal point 522. By careful design of the Fresnel plate, and the geometry and dimensions of the HTC elements, it is possible to effectively accommodate the position of the sun without any mechanical repositioning or mechanical tracking mechanism, and thus achieve concentration factors of 1X to 2X. For purposes of the illustration only two light paths are shown intersecting two different wicks in FIG. 4. However, it is to be understood that both light paths apply to all of the wicks.

HTC package 524 is a modified version of HTC package 508 in that the lateral interior and exterior surfaces are made to be reflective, and the dimensions of the HTC elements have been changed. This is a double sided Fresnel configuration. Reflective surfaces 534 and 536 are pointed out for the purpose of this description though it should be assumed that all lateral surfaces of all HTC elements in a given HTC package would be made reflective. One way in which this could be achieved would be by depositing a reflective metal such as aluminum on the surface prior to bonding of the HTC elements. By adding this reflective surface and making appropriate modifications to the dimensions of the HTC elements and the Fresnel plate, two paths are now available for concentrating light that does not strike the absorbing wick directly. The first path 530, similar to path 520 of HTC 508 where the sun's inclination is the highest. The second path 528, exploits the reflective side surface to redirect additional light to the Fresnel plate. As in the case of HTC 508, careful design of the Fresnel plate and the HTC dimensions allows for the positional range of focal points on the absorbing wick to be constrained to a large extent to the width of the absorbing wick. This design is capable of concentrations of 2.0X to 3.0X.

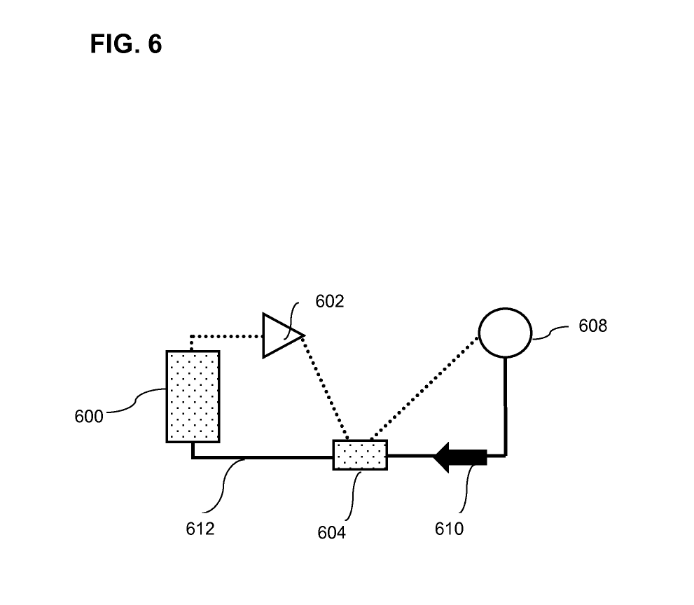

Referring now to FIG. 6, a solar thermally driven rankine cycle is illustrated, schematically. The theory of the cycle is well understood and begins with heat collected by an array of solar collectors 600 that use heat to convert a working fluid into a vapor under pressure. The heated vapor is allowed to expand in expander 602, wherein a portion of its energy is converted to mechanical work. After expansion the vapor, while lower in temperature, still contains. useful energy. Thus, it can be directed to regenerator 604 that is a heat exchanger like component. The vapor gives up more of its energy in the form of heat to the regenerator, and is subsequently directed towards condenser 608. The condenser rejects additional heat from the vapor, such that the vapor condenses into a fluid. This fluid is directed to pump 610 where it is compressed and feeds the regenerator 604. The heat from the vapor output from the expander 602, which was transferred to the regenerator, can then be used to pre-heat the fluid emerging from the pump. In this fashion the regenerator adds to the overall efficiency of the thermodynamic cycle. Traditionally solar thermal energy plants constructed to emulate this cycle are comprised of separate components, the collector, the expander, the condenser, the regenerator, and the pump. This increases cost and complexity of the system.

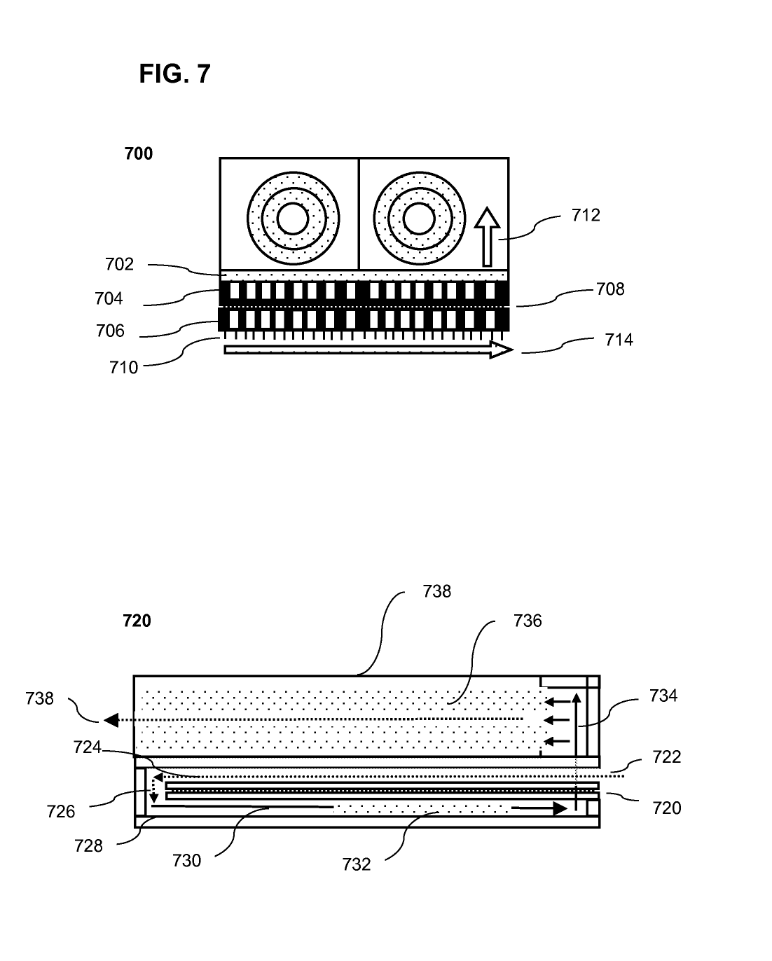

Referring now to FIG. 7, reference numeral 700 indicates a cutaway view of an integrated HTC device that comprises a HTC package with two HTC elements. It is to be understood that in other embodiments the HTC package may comprise more than two HTCs. Bonded to the bottom of the HTC package is Fresnel plate 702. Bonded to the base of the Fresnel plate is regenerator plate 704. Regenerator plate 704 is nominally a metal plate whose interior is structured to form an array of conduits or channels for the purpose of allowing vapor and fluid flow within. The channels and interior structures are designed to maximize the transfer of heat from a vapor of fluid flowing within, to the material of the regenerator, preferably the side of the regenerator bonded to the Fresnel plate in the direction of arrow 712. The bonds between the HTC core, the Fresnel plate, and the regenerator are designed to maximize thermal conductivity between the three components. The bonds may be achieved via one of a number of techniques known to those skilled in the art, including but not limited to solder based, and anodic bonding processes. Regenerator 704 is bonded to but thermally isolated from condenser plate 706. Condenser plate 706 is of a similar construction to the regenerator in that is made from metal and has an interior conduit or channel structure designed to maximize the transfer of heat from a fluid or vapor flowing within, to the exterior, preferably to the side facing away from the HTC package. Preferential heat transfer to one side may be achieved by a number of means including structuring or embossing the internal surface of the preferred side in a way which enhances its surface area. Thermal isolation between the condenser plate and the regenerator plate can be accomplished using a number of techniques known to those skilled in the art of thermo-mechanical design. One approach is to establish a small cavity 708 between the two which supports a vacuum and is physically maintained by the incorporation of glass, silica, or other thermally insulating spacer balls or structures. An airtight metal-to-metal seal, using techniques well known to those skilled in the art, can be applied to the periphery of the regenerator and condenser plates. The external pressure of the atmosphere will secure the plates together while the spacer balls or spacer structures maintains the space while minimizing thermal transfer between the two plates. Secured to the bottom of the condenser plate is an array of radiating fins 710 which serve to transfer rejected heat from the condensing vapor to the atmosphere via natural convection or a forced airflow 714.

Reference numeral 720 indicates a side view of the integrated HTC device 700 for the purpose of illustrating the flow of fluids and vapor within the integrated HTC device 700. Cooled vapor 722 arrives from the outlet of the expander (not shown) and propagates into regenerator plate 724 where it loses some of its heat. The majority of this heat is transferred via conduction to HTC element 738. The regenerator is in fluidic communication with condenser plate 728 via side conduit 726. It is through this conduit that the cooled vapor passes to the condenser where it releases sufficient heat to condense into a liquid 730. Supplemental pump 732, is a porous material matrix similar in construction to the light absorbing wicks described earlier. It does not have a light absorbing component because it will provide a pressure barrier between the vapor within the regenerator, and the condensed fluid which exits the condenser. It may also serve to provide a medium within which the vapor from the regenerator condenses. The condenser is in fluidic communication with HTC core 738 via side conduit 734. After passing through the supplemental pump, it is through side conduit 734 that liquid 730 passes to HTC 738, where it is subsequently absorbed into light absorbing wick 736. Then, and according to the aforesaid description of operation, the fluid is heated to the point of evaporation and the resulting vapor 738 can be directed to the expander. In an alternate embodiment, not shown, the working fluid passes from the condenser directly into the body of the regenerator via separately defined channels that prevent it from mixing with the vapor propagating within the regenerator. This configuration can enhance the transfer of heat from the cooling vapor within the regenerator, to the working fluid before it passes on to the HTC. Other fluid flow configurations are possible as well.

By integrating these components into a single integrated HTC system, the design of a solar thermal rankine system is greatly simplified requiring only a collection of integrated HTCs assembled to create a solar collector array, and an appropriately sized expander. Further, if the pore size and porosity of the wicks comprising the HTC elements can be appropriately defined then the need for a fluid pump in the rankine system is eliminated. This is due to the fact that capillary forces within the wick can be sufficient to maintain a pressure difference large enough to drive an expander. Pore sizes of less than a micron and preferably less than 0.1 microns are required in order to achieve reasonable thermodynamic, efficiencies. Depending on the available solar flux and the energy demands on the solar thermal system, a supplementary condenser and or supplementary liquid pump may be required. Both of these components would be smaller than their equivalents in the non-integrated rankine system.

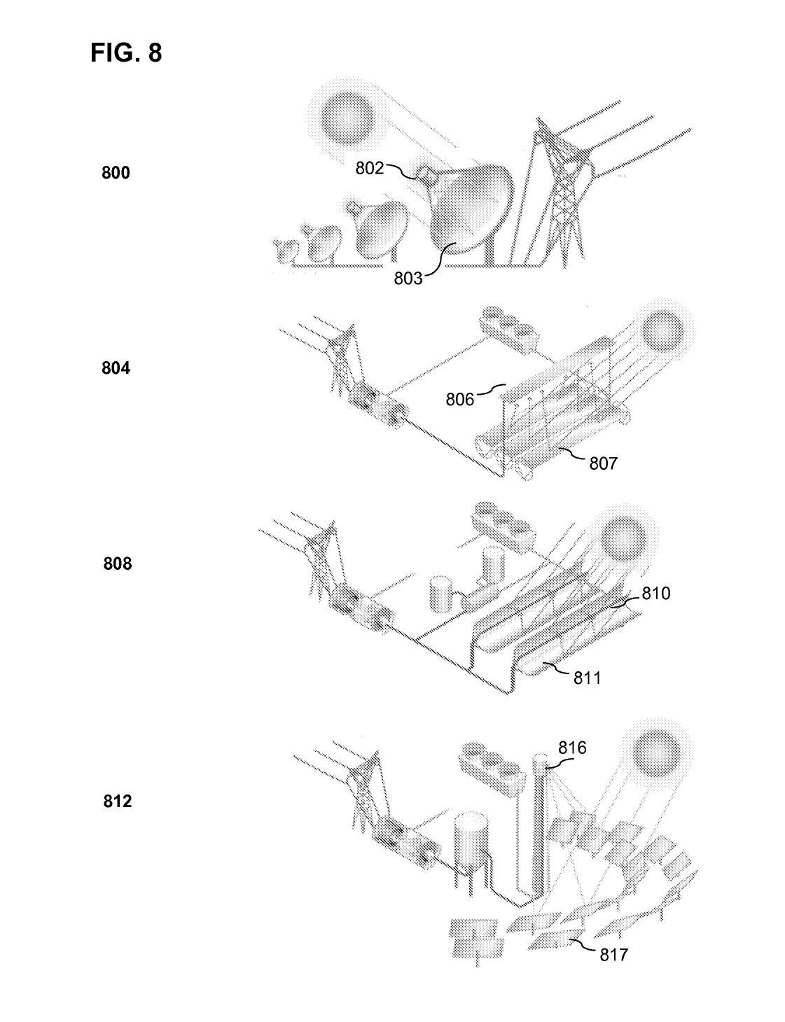

Referring now to FIG. 8, four examples of non-integrated concentrating solar power systems are shown. The examples differ primarily in the mechanism by which sunlight is concentrated. However, the principal of operation remains the same, and each example can exploit the advantages of a properly designed heat transfer core. Parabolic dish system 800 uses an array of parabolic dishes, one of which is 803, to focus the sun's rays on receiver 802. Both integrated and non-integrated heat transfer devices as described herein may be utilized in the role of the receiver 802. Fresnel reflector system 804, uses an array of movable flat mirrors 807, to focus sunlight on receiver 806. Both integrated and non-integrated HTC devices may be utilized for receiver 806 in accordance with one embodiment. Parabolic trough system 808 focuses light using a parabolic trough 811 on to receiver 810. Both integrated and non-integrated HTC devices as described herein may be utilized for receiver 810. Finally heliostat power system 812 relies on a field of tracking mirrors 817, to focus sunlight on a central receiver 816. Both integrated and non-integrated HTC devices described herein may be used to great effect in the role of the receiver 816. These are representative examples of tracking systems for focusing sunlight on to a central point for the purpose of energy generation. They are not exhaustive, but serve to illustrate the point that the heat transfer core can be utilized in any application where concentrated sunlight, focused by any means, is available for conversion into useful heat and energy. Non-tracking concentration systems including but not limited to, compound parabolic concentrators, and transmissive optics, may also be used in conjunction with the integrated and non-integrated HTC devices to advantageous effect.

Although the present invention has been described with reference to specific exemplary embodiments, it will be evident that the various modification and changes can be made to these embodiments without departing from the broader spirit of the invention. Accordingly, the specification and drawings are to be regarded in an illustrative sense rather than in a restrictive sense.

What is claimed is:

1. A heat transfer core, comprising:
at least one light absorption element to absorb heat from incident radiation thereby to heat a working fluid;
at least one fluid transfer element to cause lateral movement of the working fluid through the heat transfer core; and
a thermal conduction mitigation element to mitigate heat loss from the working fluid through conduction.

2. The heat transfer core of claim 1, wherein the light absorption element and the fluid transfer element are integrated into a single inner component, the thermal conduction mitigation element then defining an outer component positioned to be concentric to the inner component.

3. The heat transfer core of claim 2, wherein the inner component defines an inner wick and the outer component defines an outer wick.

4. The heat transfer core of claim 3, wherein the outer wick is transparent to the incident radiation.

5. The heat transfer core of claim 3, wherein the outer wick is of a material of a lower thermal conductivity than a material of the inner wick.

6. The heat transfer core of claim 3, wherein a porosity of the outer wick is such that the working fluid experiences an increase in velocity upon entering the outer wick and/or the path through which the working fluid must propagate is increased in length.

7. The heat transfer core of claim 3, wherein the outer wick defines a spiral structure.

8. The heat transfer core of claim 7, wherein the spiral structure comprises at least two layers wrapped to form the spiral structure.

9. The heat transfer core of claim 8, wherein a spacing between the layers is fixed.

10. The heat transfer core of claim 8, wherein a spacing between the layers is variable.

11. The heat transfer core of claim 9, wherein each layer comprises a transparent thin film.

12. The heat transfer core of claim 8, wherein each layer is non-porous.

13. A heat transfer core package, comprising:
at least one rectangular rod; and
a heat transfer core located within the rectangular rod, wherein the heat transfer component comprises
at least one light absorption element to absorb heat from incident radiation thereby to heat a working fluid;
at least one fluid transfer element to cause lateral movement of the working fluid through the heat transfer core; and
a thermal conduction mitigation element to heat loss from the working fluid through conduction.

14. The heat transfer core package of claim. 13, wherein the light absorption element and the fluid transfer element are defined by an inner wick, and the thermal conduction mitigation element is defined by an outer wick concentric with the inner wick.

15. The heat transfer core package of claim 14, wherein the outer wick has lower thermal conductivity than the inner wick, and accelerates the working fluid toward the inner wick and/or the path through which the working fluid must propagate is increased in length.

16. The heat transfer core package of claim 14, further comprising a light concentrating structure to focus light onto the heat transfer core.

17. The heat transfer core package of claims 16, wherein the light concentrating structure comprises a Fresnel plate.

18. The heat transfer core package of claim 13, comprising at least two layers of rectangular rods, each rectangular rod having a heat transfer core located within.

19. The heat transfer core package of claim 13, wherein each sidewall of the rectangular rod comprises has reflective internal and external surfaces.

20. A device for harnessing solar energy, comprising:
a heat transfer core to convert a working fluid to a vapor under pressure using incident solar radiation; wherein the heat transfer core transfers the vapor to an expander component;
a regenerator component to extract heat from the working fluid upon its return from the expander component and transfer said extracted heat to the heat transfer component; and
a condenser component in fluid communication with the regenerator component to condense the working fluid from the regenerator component into a liquid.

21. The device of claim 20, wherein the regenerator component and the condenser component have an internal channel structure and/or an interior surface structure to maximize heat transfer from the working fluid to a material of the regenerator component or the condenser component, as the case may be.

22. The device of claim 20, wherein the regenerator component is thermally isolated from the condenser component.

23. The device of claim 20, wherein the condenser component comprises heat fins to radiate heat to the atmosphere.

24. The device of claim 20, wherein heat transfer core is part of a heat transfer core package as claimed in claim 19.

25. The device of claim 24, wherein the heat transfer core package, regenerator component, and the condenser component are integrated.

26. A solar power system, comprising:
a device as claimed in claim 25; and
a mechanism to concentrate solar radiation onto the device.

27. The solar power system of claim 26, wherein the said mechanism comprises at least one parabolic dish.

28. The solar power system of claim 26, wherein the said mechanism comprises at least one flat mirror.

29. The solar power system of claim 26, wherein the said mechanism comprises at least one parabolic trough.

30. The solar power system of claim 26, wherein the said mechanism comprises a field of tracking mirrors.

31. The solar power system of claim 26, wherein the said mechanism comprises a compound parabolic concentrator.
